(19) United States
(12) Patent Application Publication
(10) Pub. No.: US 2012/0280745 A1
(43) Pub. Date: Nov. 8, 2012

(54) MULTI-LAYER SWITCHING IN CHARGE-DOMAIN OR SAMPLING IF FILTERS

(76) Inventors: Jianhong Fang, Nepean (CA); Thomas A. D. Riley, Osgoode (CA)

(21) Appl. No.: 13/520,709

(22) PCT Filed: Jan. 7, 2011
(86) PCT No.: PCT/CA11/00009

§ 371 Date: Jul. 5, 2012

Related U.S. Application Data
(60) Provisional application No. 61/293,392, filed on Jan. 8, 2010.

(51) Int. Cl. H03H 15/00

(52) U.S. Cl. 327/554

(57) ABSTRACT

A signal filter system which uses two groups of switches to couple tap current cells with integrating cells. The first group of switches couples tap current cells with at least one shared connection or bus while the other group of switches couples the shared connection or bus with the integrating cells. Multiple shared connections can be used and the tap current cells can be divided into groups with each group sharing at least one shared connection that is dedicated to that group. The system also allows for more than one tap current cell to simultaneously be coupled to a single integrating cell.

### TECHNICAL FIELD

The present invention relates to electronic circuits. More specifically, the present invention relates to switching systems that can be used in charge domain or sampling IF filters as well as other applications.

### BACKGROUND OF THE INVENTION

In some filters, a current distributing means is required to distribute tap currents generated from tap current cells to current integrating cells in a predetermined sequence.

Some approaches to the above, while useful, can lead to increased numbers of switches and, by extension, to chip area in semiconductor devices. Unfortunately, as chip area is usually at a premium, such approaches may not be ideal. In these approaches, any one of the tap current cells can be connected to any of the current integrating cells through a single switch. This forms a switch matrix consisting of Nt*Ns switches, where Nt is the number of the tap current cells and Ns is the number of the integrating cells. As mentioned before, the shortcoming of this implementation is that the number of switches required increases linearly with Nt and Ns. In some cases, it takes up too much space in expensive die area.

There is, therefore, a need for a new approach which provides the advantages of the above noted approaches without the disadvantages. Specifically, a new approach preferably occupies less die area than the above approaches.

### SUMMARY OF INVENTION

The present invention provides a signal filter system which uses two groups of switches to couple tap current cells with integrating cells. The first group of switches couples tap current cells with at least one shared connection or bus while the other group of switches couples the shared connection or bus with the integrating cells. Multiple shared connections can be used and the tap current cells can be divided into groups with each group sharing at least one shared connection that is dedicated to that group. The system also allows for more than one tap current cell to simultaneously be coupled to a single integrating cell.

In a first aspect, the present invention provides a filter for filtering and sampling an input signal, the filter comprising:
a plurality of tap current cells, each tap current cell being for producing at least one tap current from said input signal;
a plurality of integrating means, for each current integrating cell being for receiving and integrating a tap current;
current sampling means for sampling and resetting contents of said current integrating cells;
current distribution means for coupling said tap current cells with said current integrating cells

wherein

said current distribution means is controlled by a plurality of first clock signals and said current sampling means is controlled by at least one second clock signal and

wherein

said current distribution means comprises a plurality of switches, an opening and closing of said switches being in a predetermined sequence as controlled by said plurality of first clock signals, said predetermined sequence including simultaneously coupling more than one tap current cell to a single integrating means.

In another aspect, the present invention provides a filter for filtering and sampling an input signal, the filter comprising:
at least two tap current sources, each tap current source being for producing at least one tap current from said input signal;
a plurality of current integrating cells, each current integrating cell being for receiving and integrating a tap current;
a plurality of current sampling cells, each current sampling cell being for sampling and resetting a specific current integrating cell, said sampling cells providing an output for said filter;
at least one set of first connector lines;
one set of second connector lines, each one of said second connector lines being coupled to a specific current integrating cell;
at least two sets of first switches, each set of first switches being associated with a specific tap current source, each first switch in each set of first switches being controlled by a specific first control clock signal such that said first control clock signal controls an activation or deactivation of said first switch and an activation of said first switch coupling a specific tap current source to a specific one of said first connector lines;
a plurality of sets of second switches, each set of second switches being associated with a specific first connector line, each second switch of each set of second switches being controlled by a specific second control clock signal such that said second control clock signal controls an activation or deactivation of said second switch and an activation of said second switch couples a specific first connector line with a specific second connector line;

wherein
an activation and deactivation of said first and second switches is in a predetermined sequence;
an activation of specific first and second switches creates a signal path from at least one tap current source to a specific current integrating cell.

A further aspect of the invention provides a filter for filtering and sampling an input signal, the filter comprising:
at least two tap current cells, each tap current cell being for producing at least one tap current from said input signal
a plurality of current integrating cells, each current integrating cell being for receiving and integrating a tap current
a plurality of current sampling cells, each current sampling cell being for sampling and resetting a specific current integrating cell
at least one set of first connector lines
one set of second connector lines, each one of said second connector lines being coupled to a specific current integrating cell
at least two first switches, each first switch being associated with a specific tap current cell, each first switch being controlled by a specific first control clock signal such that said first control clock signal controls an activation or deactivation of said first switch and an activation of said first switch couples a specific tap current cell to a specific one of said first connector lines
at least two sets of second switches, each set of second switches being associated with a specific first connector line, each second switch of each set of second switches being controlled by a specific second control clock signal such that said second control clock signal controls an activation or deactivation of said second switch and an activation of said second switch couples a specific first connector line with a specific second connector line

wherein
an activation and deactivation of said first and second switches is in a predetermined sequence
an activation of specific first and second switches creates a signal path from at least one tap current cell to a specific current integrating cell.

A final aspect of the invention provides a filter for filtering and sampling an input signal, the filter comprising:
a plurality of tap current cells, each tap current cell being for producing at least one tap current from said input signal
a plurality of integrating cells, each integrating cell being for receiving and integrating a tap current
a plurality of current sampling cells for sampling and resetting contents of said current integrating cells
a first set of connector lines
a second set of connector lines, each second connector line being coupled to a specific current integrating cell
a first set of switches, each one of said first set of switches being for coupling a specific tap current cell to a specific one of said first set of connector lines, each one of said first set of switches being controlled by a specific first control clock signal
a second set of switches, each one of said second set of switches being for coupling a specific first connector line to a specific second connector line, each one of said second set of switches being controlled by a specific second control clock signal

wherein
an activation and deactivation of said first and second switches is in a predetermined sequence
an activation of specific first and second switches creates a signal path from at least one tap current cell to a specific current integrating cell.

### BRIEF DESCRIPTION OF THE DRAWINGS

The invention will be described with reference to the accompanying drawings, wherein

FIG. 1 is a schematic illustration of a first embodiment of the present invention;

FIG. 2 is a timing diagram of the clock signals which control the switches in FIG. 1;

FIG. 3 shows, at each input clock cycle, the current that being integrated by each integrating cell in FIG. 1;

FIG. 4 is a schematic illustration of a second embodiment of the present invention;

FIG. 5 is a timing diagram of the clock signals which control the switches in FIG. 4;

FIG. 6 shows, at each input clock cycle, the current that being integrated by each integrating cell in FIG. 4;

FIG. 7 is a timing diagram of the first set of clocks used in a third embodiment;

FIG. 8 shows, at each input clock cycle, the current that being integrated by each integrating cell in the third embodiment;

FIG. 9 is a schematic illustration of a fourth embodiment of the present invention;

FIG. 10 is a timing diagram of the clock signals which control the switches in FIG. 9;

FIG. 11 shows, at each input clock cycle, the current that being integrated by each integrating cell in FIG. 10; and

FIG. 12 illustrates a block diagram of a general system design according to one aspect of the invention.

### DETAILED DESCRIPTION OF THE INVENTION

The present invention can be implemented in different embodiments. The following are examples of specific embodiments which implement the invention.

The reader is directed to U.S. Provisional Patent Application 60/996,408 (filed 15 Nov. 2007) and to PCT Application PCT/CA2008/002004 (filed 14 Nov. 2008 and published as WO 2009/062306) for further background information which may assist in the understanding of the present invention. The above documents in their entirety are hereby incorporated by reference.

Further information regarding sampling filters may be found in the following references, both of which are hereby incorporated by reference in their entirety:
Muhammad K & Staszewski RB (2004) Direct RF sampling mixer with recursive filtering in charge domain. Proceedings of the IEEE International Symposium on Circuits and Systems (ISCAS'04), Vancouver, Canada, May 23-26 2004, 1: 577-580.
Karvonen S, Riley T & Kostamovaara J (2001) A low noise quadrature subsampling mixer. Proceedings of the International Symposium on Circuits and Systems (ISCAS'2001), Sydney, Australia, 4: 790-793.

One advantage of the invention is that it requires a smaller number of switches to distribute the current compared to the implementation in PCT Application PCT/CA2008/002004 when Nt (number of tap current cells) and Ns (number of sampling cells) are large.

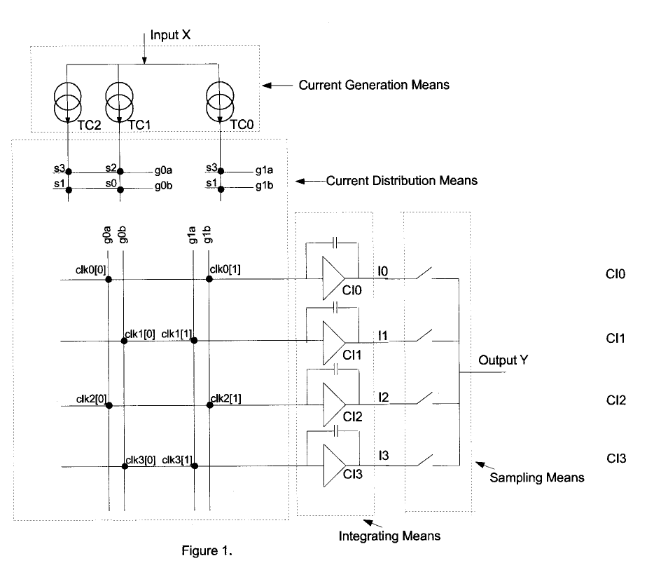

In one embodiment of the invention, illustrated in FIG. 1, the sampling filter comprises a tap current generating means that generates three tap currents where each tap current is proportional to an input signal with some predetermined proportionality constant, TC2, TC1, and TC0, an array of integrating means that consists of four integrating cells CI3, CI2, CI1 and CI0, a current distribution means that sending the three tap currents to the four integrating cells, and a sampling and resetting means.

In FIGS. 1, 4, and 9, a dot represents a switch that connects the two lines that pass across the dot. The clock signal that controls the opening/closing (or activation/deactivation) operation of a switch is noted beside the dot. A switch is closed when the corresponding control clock is high and open otherwise.

In this first embodiment, the three tap currents are divided into two groups TCG0 and TCG1. Group TCG0 consists of tap current cells TC2 and TC1. Group TCG1 consists only of tap current cell TC0. The number of the members in each group is determined by the sub-sample ratio which will be explained later. Each group in this example is connected to a dedicated intermediate two-line bus or a shared connection. For example, tap current group TCG0 is connected to the buses g0a and g0b. TCG1 is connected to the buses g1a and g1b. Each member of a group can be connected or coupled to any line of its corresponding bus or buses. Thus, either of TC1 or TC2 can be coupled to either bus g0a or g0b. An integrating cell (CI0-CI3) is able to access, by way of a corresponding line, each of the various buses as illustrated in FIG. 1. For example, CI0 is able to connect to buses g0a and g1b (by way of switches controlled by clock signals clk0[0] and clk0[1] respectively), CI1 to g0b and g1a (by way of switches controlled by clock signals clk1[0] and clk1[1]), CI2 to g0a and g1b (by way of switches controlled by clock signals clk2[0] and clk2[1]), and CI3 to g0b and g1a (by way of switches controlled by clock signals clk3[0] and clk3[1]). As can be seen from FIG. 1, the tap current cells couple to their respective bus or buses by way of switches controlled by specific clock signals. As an example, tap current cell TC2's connection to bus g0a is controlled by clock signal s3. As another example, tap current TC1 couples to bus g0b by way of a switch controlled by clock signal s0.

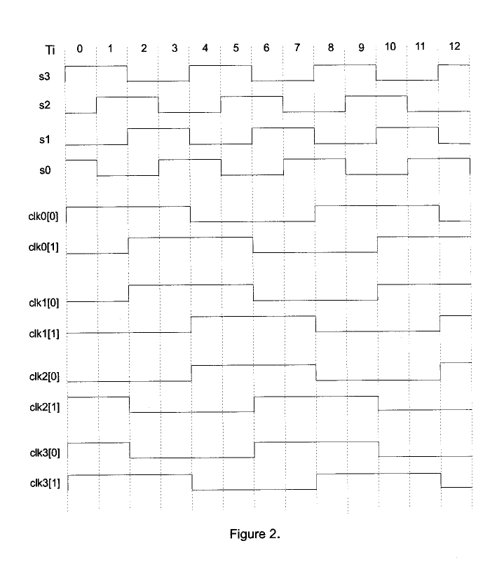

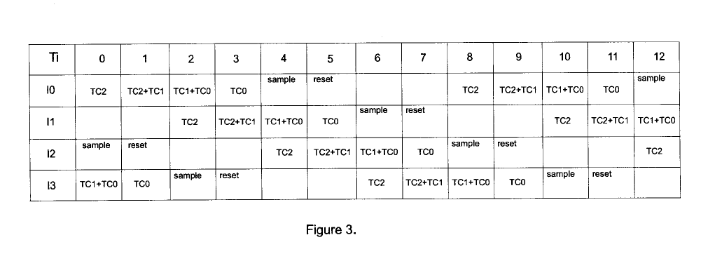

The timing diagram for the various clock signals is illustrated in FIG. 2. FIG. 3 details which integrating cell is receiving which tap current signal at which time interval. It should be noted that, in FIG. 3, the top row indicates the time interval while the leftmost column indicates which integrating cell is receiving a tap current signal.

As can be seen from FIG. 2 and FIG. 3, at Ti=0, the integrating cell CI0 receives current from TC2 following the path TC2→g0a→CI0 by closing the switches controlled by clock s3 and clk0[0]. At Ti=1, in addition to the current from TC2, CI0 receives the current from TC1 following the path TC1→g0a→CI0 by closing the switches controlled by clock s2 and clk0[0]See FIG. 3 for details as to which tap current is being received by which integrating cell at which time period. As can be seen, from FIG. 3 shows the current being integrated at each Ti and this corresponds to the clock time diagram illustrated in FIG. 2.

At the end of Ti=3, the output from CI, by integrating all the current from Ti=0 to Ti=3 is:

$$\begin{matrix}I 0 [ 3 ] = TC 2 & * X [ 0 ] & ; Ti = 0 \\ + ( TC 2 + TC 1 ) & * X [ 1 ] & ; Ti = 1 \\ + ( TC 1 + TC 0 ) & * X [ 2 ] & ; Ti = 2 \\ + TC 0 & * X [ 3 ] & ; Ti = 3\end{matrix}$$

As can be seen, I0[3] is sampled as the valid output at Ti=3. Then CI0 is reset and starts a new integrating period.

The next valid output sequence is, from FIG. 3, I1[5]→I2[7]→I3[9]→I0[11]→I1[13] . . . . This means that a valid output is available at these integrating cells at that time period.

At Ti=N, (N=3, 5, 7, 9 . . . ), the output can be written as:

$$\begin{matrix}Y [ N ] = TC 2 & * X [ N - 3 ] & ; T i = N - 3 \\ + ( TC 2 + TC 1 ) & * X [ N - 2 ] & ; Ti = N - 2 \\ + ( TC 1 + TC 0 ) & * X [ N - 1 ] & ; Ti = N - 1 \\ + TC 0 & * X [ N ] & ; Ti = N\end{matrix}$$

This can also be expressed as:

Y[N]=[1 1] conv [TC2 TC1 TC0] conv [X[N−3]X[N−2]X[N−1]X[N]]

Translating this into transfer function H(z) yields

$$H ( z ) = [ 1 - \frac{1}{z} ] * [ TC 0 + \frac{TC 1}{z} + \frac{TC 2}{{z}^{2}} ] .$$

The sampling filter therefore performs two FIRs, the first one [1 1] as a pre-filter comes free by setting pulse width of clock s3, s2, s1, s0 to be 2Ti. The second one [TC0 TC1 TC2] is what set out to accomplish.

The output Y is sampled at every other Ti cycle. The sub-sample ratio is therefore two.

The total number of switches required can be calculated using following formula:

$$2 * Nt + Ns ⌈ \frac{Nt}{Nconv} ⌉$$

where Nt is the number of taps, Nconv is the sub-sample ratio, and Ns is the even number of the samplers.

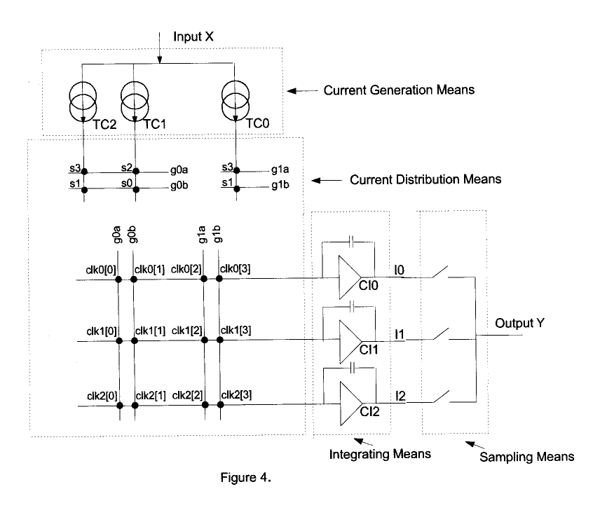

For the second embodiment, the analysis on the first embodiment can be applied. A circuit diagram of the second embodiment is shown in FIG. 4, where the number of integrating cells is odd. (It should be noted that there was an even number of integrating cells in the first embodiment.)

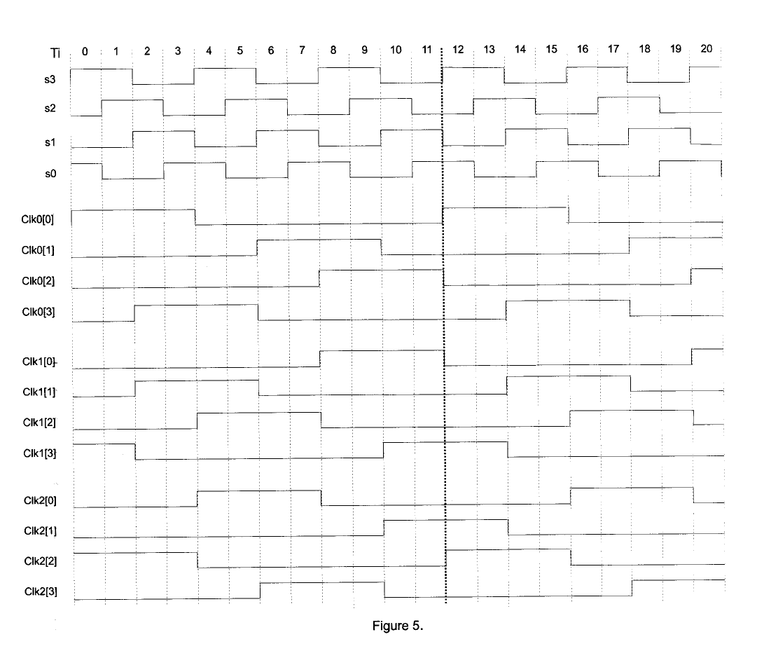

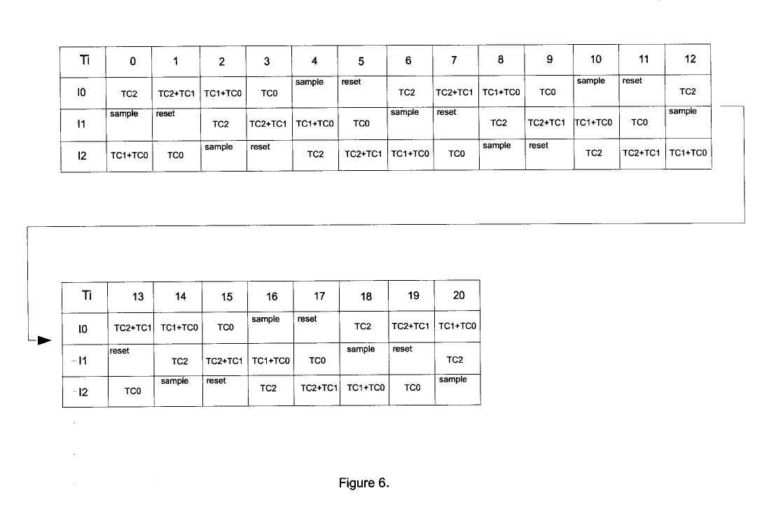

At Ti=0, the integrating cell CI0 receives current from TC2 following the path TC2→g0a→CI0 by closing the switches controlled by clocks s3 and clk0[0]. At Ti=1, in addition to the current from TC2, CI0 receives the current from TC1 following the path TC1→g0a→CI0 by closing the switches controlled by clock s2 and clk0[0]. The timing diagram for the various switches in FIG. 4 can be seen in FIG. 5 while the sequence of tap currents being coupled to the various integrating cells can be found in FIG. 6. As with the first embodiment, the sequence in FIG. 6 corresponds to the timing diagram in FIG. 5. It should be noted that, as with the first embodiment and as can be seen in FIGS. 6 and 3, more than one tap current cell is simultaneously coupled to a single integrating cell (see Ti=2 in FIG. 6 as an example).

At the end of Ti=3, the output from CI, by integrating all the current from Ti=0 to Ti=3 is:

$$\begin{matrix}I 0 [ 3 ] = TC 2 & * X [ 0 ] & ; T i = 0 \\ + ( TC 2 + TC 1 ) & * X [ 1 ] & ; Ti = 1 \\ + ( TC 1 + TC 0 ) & * X [ 2 ] & ; Ti = 2 \\ + TC 0 & * X [ 3 ] & ; Ti = 3\end{matrix}$$

I0[3] is sampled as the valid output at Ti=3. Then CI0 is reset and starts a new integrating period.

The next sequence of valid outputs for this embodiment is therefore I1[5]→I2[7]→I0[9]→I1[I1]→I2[13]→I0[15] . . . .

At Ti=N, (N=3, 5, 7, 9 . . . ), the output can be written as:

$$\begin{matrix}Y [ N ] = TC 2 & * X [ N - 3 ] & ; T i = N - 3 \\ + ( TC 2 + TC 1 ) & * X [ N - 2 ] & ; Ti = N - 2 \\ + ( TC 1 + TC 0 ) & * X [ N - 1 ] & ; Ti = N - 1 \\ + TC 0 & * X [ N ] & ; Ti = N\end{matrix}$$

This can also be expressed as:

Y[N]=[1 1] conv [TC2 TC1 TC0] conv [X[N−3]X[N−2]X[N−1]X[N]]

This translates into the transfer function H(z)

$$H ( z ) = [ 1 - \frac{1}{z} ] * [ TC 0 + \frac{TC 1}{z} + \frac{TC 2}{{z}^{2 }} ]$$

This sampling filter therefore performs two FIRs, the first one [1 1] comes free by setting the pulse width of clock s3, s2, s1, s0 to be 2Ti. The second one [TC0 TC1 TC2] is what was desired.

The output Y is sampled at every other Ti cycle, which makes the sub-sample ratio to be two.

The total number of switches required can be calculated using following formula:

$$2 * Nt + 2 * Ns * ⌈ \frac{Nt}{Nconv} ⌉$$

where Nt is the number of taps, Nconv is the sub-sample ratio, and Ns is the odd number of the samplers.

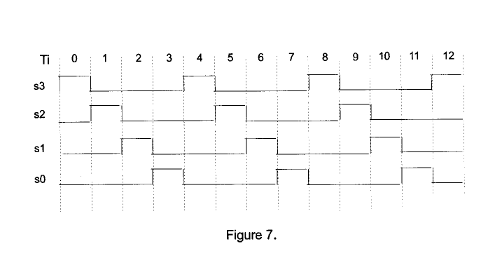

A third embodiment of the invention is a special case of the first embodiment. Pre-filtering is eliminated by by setting the pulse width of clock s3,s2,s1,s0 to be equal to one Ti cycle. The timing diagram for clocks s3,s2,s1,s0 in this embodiment can be found in FIG. 7.

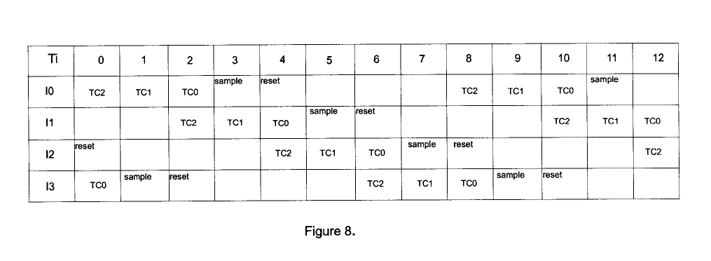

At Ti=0, the integrating cell CI0 receives current from TC2 following the path TC2→g0a→CI0 by closing the switches controlled by clock s3 and clk0[0]. At Ti=1, CI0 receives the current from TC1 following the path TC1→g0a→CI0 by closing the switches controlled by clock s2 and clk0[0]. FIG. 8 shows the sequence of which tap currents are coupled to which integrating cell at which time period.

As can be seen from FIG. 8, at the end of Ti=2, the output from CI, by integrating all the current from Ti=0 to Ti=2 is:

$$\begin{matrix}I 0 [ 2 ] = TC 2 & * X [ 0 ] & ; T i = 0 \\ + TC 1 & * X [ 1 ] & ; Ti = 1 \\ + TC 0 & * X [ 2 ] & ; Ti = 2\end{matrix}$$

I0[2] is sampled as the valid output at Ti=2. CI0 is then reset and it starts a new integrating period.

The next sequence of valid outputs is then (from FIG. 8) I1[4]→I2 [6]→I3[8]→I0[10]→I1[I2]→I0[1] . . . .

At Ti=N, (N=2, 4, 6, 8 . . . ), the output can be written as:

$$\begin{matrix}Y [ N ] = TC 2 & * X [ N - 2 ] & ; T i = N - 2 \\ + TC 1 & * X [ N - 1 ] & ; Ti = N - 1 \\ + TC 0 & * X [ N ] & ; Ti = N\end{matrix}$$

This output can also be expressed as:

Y[N]=[TC2 TC1 TC0] conv [X[N−2]X[N−1]X[N]]

and this translates into the transfer function H(z)

$$H ( z ) = [ TC 0 + \frac{TC 1}{z} + \frac{TC 2}{{z}^{2}} ]$$

This sampling filter therefore performs the FIR with tap coefficients [TC0 TC1 TC2]. The output Y is sampled at every other Ti cycle, which makes the sub-sample ratio to be two.

The total number of switch required is the same as in the first embodiment:

$$2 * Nt * Ns * ⌈ \frac{Nt}{Nconv} ⌉$$

where Nt is the number of taps, Nconv is the sub-sample ratio, and Ns is the even number of the samplers

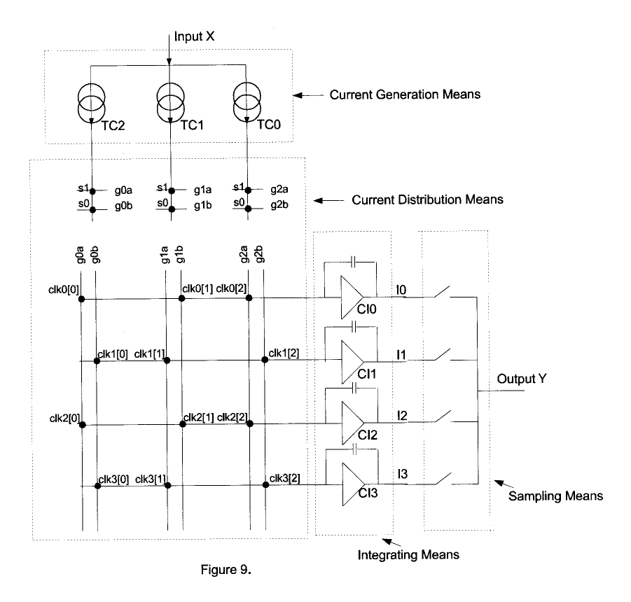

A fourth embodiment is another special case of the first embodiment. There is no sub-sampling in the fourth embodiment. Each tap current forms its own group as illustrated in FIG. 9.

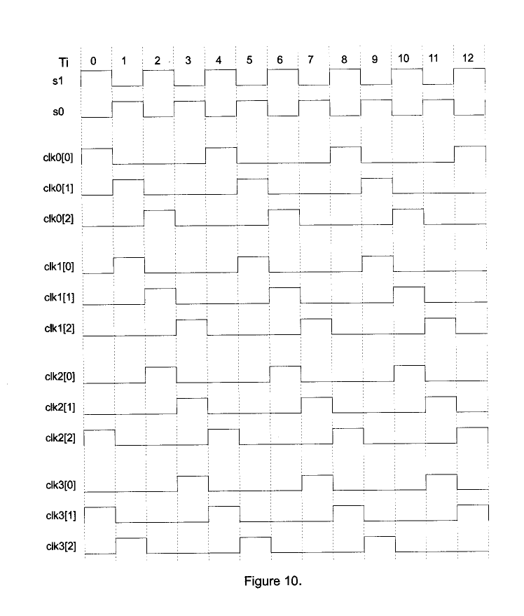

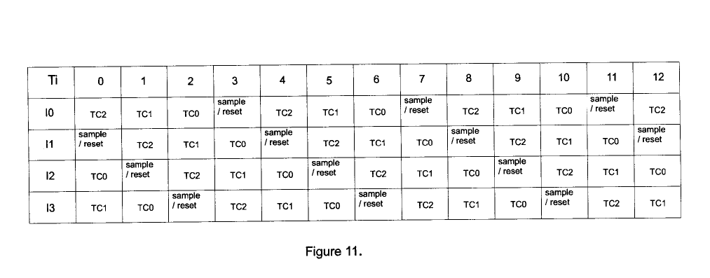

At Ti=0, The integrating cell CI0 receives current from TC2 following the path TC2→g0a→CI0 by closing the switches controlled by clock s1 and clk0[0]. At Ti=1, CI0 receives the current from TC1 following the path TC1→g1b→CI0 by closing the switches controlled by clock s0 and clk0[1]. At Ti=2, CI0 receives the current from TC0 following the path TC0→g2a→CI0 by closing the switches controlled by clock s1 and clk0[2]. FIG. 10 illustrates a timing diagram for the various clock signals used to control the circuit of FIG. 9 while FIG. 11 shows which tap current cell is being integrated by which integrating cell at which time period. Of course, the data in FIG. 11 accords with the timing diagram of FIG. 10.

At the end of Ti=2, the output from CI, by integrating all the current from Ti=0 to Ti=2, is:

$$\begin{matrix}I 0 [ 2 ] = TC 2 & * X [ 0 ] & ; T i = 0 \\ + TC 1 & * X [ 1 ] & ; Ti = 1 \\ + TC 0 & * X [ 2 ] & ; Ti = 2\end{matrix}$$

I0[2] is sampled as the valid output at Ti=2. CI0 is then reset and starts a new integrating period.

The next sequence of valid outputs is (from FIG. 11):

I1[3]→I2 [4]→I3[5]→I0[6]→I1[7]→I2 [8] . . .

At Ti=N, (N=2, 3, 4, 5, . . . ), the output can be written as:

$$\begin{matrix}Y [ N ] = TC 2 & * X [ N - 2 ] & ; T i = N - 2 \\ + TC 1 & * X [ N - 1 ] & ; Ti = N - 1 \\ + TC 0 & * X [ N ] & ; Ti = N\end{matrix}$$

As with the other embodiments, this can also be expressed as:

Y[N]=[TC2 TC1 TC0] conv [X[N−2]X[N−1]X[N]]

and this translates into the transfer function H(z)

$$H ( z ) = [ TC 0 + \frac{TC 1}{z} + \frac{TC 2}{{z}^{2}} ]$$

This sampling filter therefore performs the FIR with tap coefficients [TC0 TC1 TC2].

The output Y is sampled at every Ti cycle, which means there is no sub-sampling occurring.

The total number of switch required can be calculated using the same formula as the first embodiment:

$$2 * Nt + 2 * Ns * ⌈ \frac{Nt}{Nconv} ⌉$$

where Nt is the number of taps, Nconv is the sub-sample ratio (in this embodiment, Nconv=1), and Ns is the odd number of the samplers.

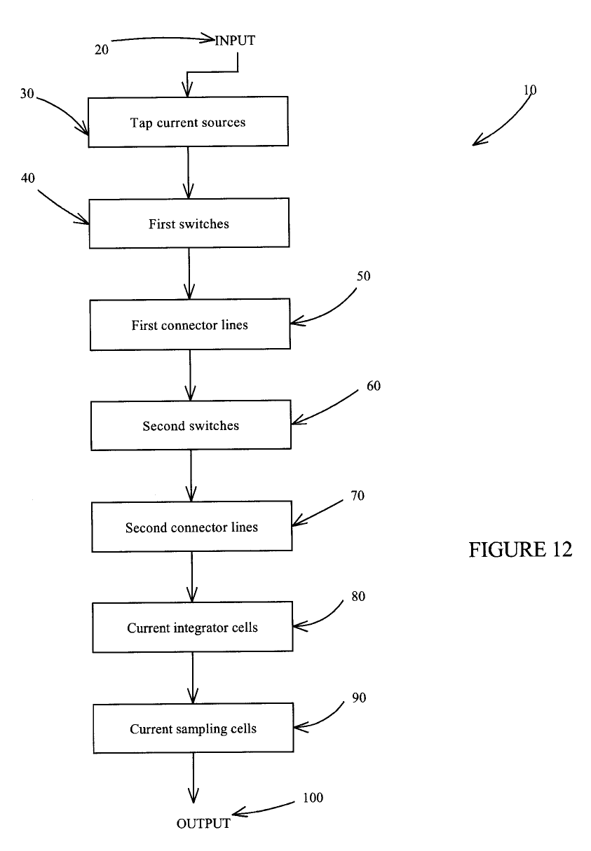

It should be noted that the embodiments noted above are specific implementations of a system design as illustrated in FIG. 12. As can be seen from the Figure, the system 10 has an input 20 which is fed into tap current sources 30. The tap current sources 30 can be multiple tap current cells, each tap current cell producing a tap current derived from the input 20. As noted above, the tap current cells can be grouped into discrete groups (see FIG. 1) or they can be individual cells (see FIG. 4). The tap current sources are attached to a group of first switches 40, each of which is controlled by first control signals. The first switches couple specific tap current sources to specific first connector lines 50. The first control signals control the opening and closing of the first switches and they thereby control which tap current source couples to which first connector line.

The first connector lines 50 are coupled to second connector lines 70 by way of second switches 60. As seen in FIGS. 1, 4, and 9, second switches couple the first connector lines with the second connector lines. The second connector lines couple to the current integrator cells 80. The current integrator cells 80 then couple to the current sampling cells 90. These current sampling cells 90 then produce the output 100.

As an aid to understanding the correspondence between FIG. 1 and FIG. 12, in FIG. 1 the tap current sources are the tap current cells TC0, TC1, and TC2. The first switches are the switches controlled by clock signals s0, s1, s2, and s3. First connector lines are the buses g0a, g0b, g1a, and g1b. Second switches are the switches controlled by the clock signals clk0[0], clk0[1], clk1[0], clk1[1], clk2[0], clk2[1], clk3[0], and clk3[1]. The second switches couple the first connector lines with the second connector lines that couple (in these embodiments) directly to the current integrator cells CI0, CI1, CI2, and CI3. These current integrator cells are each coupled to the sampling cells I0, I1, I2, and I3.

It should be noted that each of the embodiments in FIGS. 1, 4, and 9 have components that correspond to the blocks in FIG. 12.

A person understanding this invention may now conceive of alternative structures and embodiments or variations of the above all of which are intended to fall within the scope of the invention as defined in the claims that follow.

Having thus described the invention, what is claimed as new and secured by Letters Patent is:

1. A filter for filtering and sampling an input signal, the filter comprising:
at least two tap current sources, each tap current source being for producing at least one tap current from said input signal;
a plurality of current integrating cells, each current integrating cell being for receiving and integrating a tap current;
a plurality of current sampling cells, each current sampling cell being for sampling and resetting a specific current integrating cell, said sampling cells providing an output for said filter;
at least one set of first connector lines;
one set of second connector lines, each one of said second connector lines being coupled to a specific current integrating cell;
at least two sets of first switches, each set of first switches being associated with a specific tap current source, each first switch in each set of first switches being controlled by a specific first control clock signal such that said first control clock signal controls an activation or deactivation of said first switch and an activation of said first switch coupling a specific tap current source to a specific one of said first connector lines;
a plurality of sets of second switches, each set of second switches being associated with a specific first connector line, each second switch of each set of second switches being controlled by a specific second control clock signal such that said second control clock signal controls an activation or deactivation of said second switch and an activation of said second switch couples a specific first connector line with a specific second connector line;
wherein
an activation and deactivation of said first and second switches is in a predetermined sequence;
an activation of specific first and second switches creates a signal path from at least one tap current source to a specific current integrating cell.

2. A filter according to claim 1 wherein each one of said at least two tap current sources comprises at least one tap current cell.

3. A filter according to claim 2 wherein each one of said at least two tap current sources comprises a group of tap current cells, and wherein each one of said first switches coupling a specific tap current cell to a specific first connector line when said first switch is activated

4. A filter according to claim 1 wherein each current sampling cell comprises a sampling switch.

5. A filter for filtering and sampling an input signal, the filter comprising:
a plurality of tap current cells, each tap current cell being for producing at least one tap current from said input signal;
a plurality of integrating means, for each current integrating cell being for receiving and integrating a tap current;
current sampling means for sampling and resetting contents of said current integrating cells;
current distribution means for coupling said tap current cells with said current integrating cells
wherein
said current distribution means is controlled by a plurality of first clock signals and said current sampling means is controlled by at least one second clock signal and
wherein
said current distribution means comprises a plurality of switches, an opening and closing of said switches being in a predetermined sequence as controlled by said plurality of first clock signals, said predetermined sequence including simultaneously coupling more than one tap current cell to a single integrating means.

6. A filter according to claim 5 wherein said current distribution means comprises a first group of switches and a second group of switches, said first group of switches being for coupling said tap currents to at least one shared connection and said second group of switches being for coupling said at least one shared connection to said plurality of integration means.

7. A filter according to claim 6 wherein each switch in said groups of switches is controlled by a clock signal independent of other switches.

8. A filter according to claim 6 wherein the or each of said at least one shared connection couples a specific tap current cell to said second group of switches only when a specific switch coupled between said specific tap current cell and said shared connection is active.

9. A filter according to claim 5 wherein said tap current cells are divided into tap current cell groups, each tap current cell group sharing at least one shared connection to said plurality of integrating means, each tap current cell in a tap current cell group being coupled to an integrating means only when a specific switch on a specific shared connection is active.

10. A filter for filtering and sampling an input signal, the filter comprising:
at least two tap current cells, each tap current cell being for producing at least one tap current from said input signal
a plurality of current integrating cells, each current integrating cell being for receiving and integrating a tap current
a plurality of current sampling cells, each current sampling cell being for sampling and resetting a specific current integrating cell
at least one set of first connector lines
one set of second connector lines, each one of said second connector lines being coupled to a specific current integrating cell
at least two first switches, each first switch being associated with a specific tap current cell, each first switch being controlled by a specific first control clock signal such that said first control clock signal controls an activation or deactivation of said first switch and an activation of said first switch couples a specific tap current cell to a specific one of said first connector lines
at least two sets of second switches, each set of second switches being associated with a specific first connector line, each second switch of each set of second switches being controlled by a specific second control clock signal such that said second control clock signal controls an activation or deactivation of said second switch and an activation of said second switch couples a specific first connector line with a specific second connector line
wherein
an activation and deactivation of said first and second switches is in a predetermined sequence
an activation of specific first and second switches creates a signal path from at least one tap current cell to a specific current integrating cell.

11. A filter for filtering and sampling an input signal, the filter comprising:
a plurality of tap current cells, each tap current cell being for producing at least one tap current from said input signal
a plurality of integrating cells, each integrating cell being for receiving and integrating a tap current
a plurality of current sampling cells for sampling and resetting contents of said current integrating cells
a first set of connector lines
a second set of connector lines, each second connector line being coupled to a specific current integrating cell
a first set of switches, each one of said first set of switches being for coupling a specific tap current cell to a specific one of said first set of connector lines, each one of said first set of switches being controlled by a specific first control clock signal
a second set of switches, each one of said second set of switches being for coupling a specific first connector line to a specific second connector line, each one of said second set of switches being controlled by a specific second control clock signal
wherein
an activation and deactivation of said first and second switches is in a predetermined sequence
an activation of specific first and second switches creates a signal path from at least one tap current cell to a specific current integrating cell.
